(19) United States
(12) Patent Application Publication
(10) Pub. No.: US 2012/0072806 A1
(43) Pub. Date: Mar. 22, 2012

(54) SEMICONDUCTOR MEMORY DEVICE

(76) Inventors: Koji TABATA, Yokohama-shi (JP); Hidetoshi SAITO, Yamato-shi (JP); Mitsuhiro ABE, Kawasaki-shi (JP); Tokumasa HARA, Kawasaki-shi (JP)

(21) Appl. No.: 13/157,638

(22) Filed: Jun. 10, 2011

(30) Foreign Application Priority Data
Sep. 21, 2010 (JP) 2010-211269

(51) Int. Cl. G11C 29/04; G06F 11/16

(52) U.S. Cl. 714/773; 714/764; 714/E11.056

(57) ABSTRACT

According to one embodiment, a semiconductor memory device includes a memory including an array of memory cells. A buffer comprises latches to hold data from the memory cells. The latches constitute latch groups. The latches of each latch group are connected to corresponding one common line through a transfer circuit. An error corrector is connected to the common lines and detects an error bit in received data. A data transfer controller causes the buffer to read out data from memory cells to be verified, repeats reading out of all data in the latches in one latch group to corresponding one of common lines as to-be-verified data segment for different latch groups, and transfers the to-be-verified data segments to the error corrector. A verify controller causes the error corrector to determine whether an error bit is included in to-be-verified data includes the to-be-verified data segments.

### CROSS-REFERENCE TO RELATED APPLICATIONS

This application is based upon and claims the benefit of priority from Japanese Patent Application No. 2010-211269, filed Sep. 21, 2010; the entire contents of which are incorporated herein by reference.

### FIELD

Embodiments described herein relate generally to a semiconductor memory device.

### BACKGROUND

A NAND flash memory is known as an example of a semiconductor memory device. A NAND flash memory holds data by utilizing different thresholds of memory cell transistors. In a NAND flash memory, data is written in units called a page comprising a plurality of memory cells, and erased in units of blocks each comprising a plurality of serial pages.

In a flash memory, verification is performed after writing (, or programming) and erasing data. Verification is for confirming that data is correctly written in an object memory cell, or erased from an object block. In particular, when a memory cell transistor to be verified holds data exceeding a target threshold, corresponding data (e.g., “1”) is read to a page buffer from the object memory cell. On the other hand, when a memory cell transistor to be verified holds data not exceeding a target threshold, “0” is read to a page buffer. The data read from object memory cells to a page buffer, i.e., to-be-verified data, is determined whether to have “1” in all bits. When all bits of the data is “1”, the verification is determined to be a pass. When the verification fails, the data is rewritten to an object page or re-erased from an object block.

In the above example, when even one bit that is not an expected value (, or determined to be a fail) is present in a page when writing, or in a block when erasing, verification is determined to be a fail (referred to as a batch detection). Therefore, verification is possible through determination via calculation of OR (, or logical product) of all data in a page buffer, for example, and a configuration for such implementation is simple.

In a flash memory, an error correction circuit (ECC) may be provided outside or on a flash memory chip. An ECC is provided to compensate a decrease in the reliability caused by miniaturization of a flash memory. An ECC can also be used to save a fail bit. Therefore, verification is determined to be a pass in an actual device or at the time of D/S even when a predetermined number of fail bits, e.g., three, whose number is determined based on the number of bits savable by an ECC is present. Such determination is called a pseudo-pass, for example, and improves the yield of products.

For determination of the pseudo-pass, fail bits included in to-be-verified data must be counted. This counting requires an exclusive detection circuit, which causes an increase in a circuit area necessary for verification.

### BRIEF DESCRIPTION OF THE DRAWINGS

FIG. 1 is a diagram illustrating a page buffer, a detection circuit, and batch detection in a reference example;

FIG. 2 is a diagram illustrating a page buffer, a detection circuit, and fail bit counting in a reference example;

FIG. 3 is a schematic block diagram of a semiconductor memory device according to a first embodiment;

FIG. 4 is a circuit diagram of a specific example of a block;

FIG. 5 is a specific sectional view of a block;

FIG. 6 is a schematic diagram illustrating a circuit configuration of a page buffer of a semiconductor memory device according to a first embodiment;

FIG. 7 is a schematical flowchart of verification by a semiconductor memory device according to a first embodiment;

FIG. 8 is a schematical flowchart of verification by a semiconductor memory device according to a second embodiment;

FIG. 9 is a schematical flowchart of verification and rewriting by a semiconductor memory device according to a third embodiment;

FIG. 10 is a schematical flowchart of verification by a semiconductor memory device according to a fourth embodiment;

FIG. 11 is a schematical flowchart of verification by a semiconductor memory device according to a fifth embodiment; and

FIG. 12 is a schematical flowchart of verification by a semiconductor memory device according to a sixth embodiment.

### DETAILED DESCRIPTION

In general, according to one embodiment, a semiconductor memory device includes a memory, a buffer, an error corrector, a data transfer controller, and a verify controller. The memory comprises an array of memory cells. The buffer comprises latches to hold data from the memory cells. The latches constitute latch groups. The latches of each latch group are connected to corresponding one of common lines through a transfer circuit. The error corrector is connected to the common lines and detects an error bit in received data. The data transfer controller causes the buffer to read out data from memory cells to be verified in verify operation, repeats reading out of all data held in the latches in one latch group to corresponding common line as to-be-verified data segment for different latch groups, and transfers the to-be-verified data segments to the error corrector. The verify controller causes the error corrector to determine whether an error bit is included in to-be-verified data comprising the to-be-verified data segments.

The inventors have acquired the following findings in the process of development of embodiments.

### Reference Example

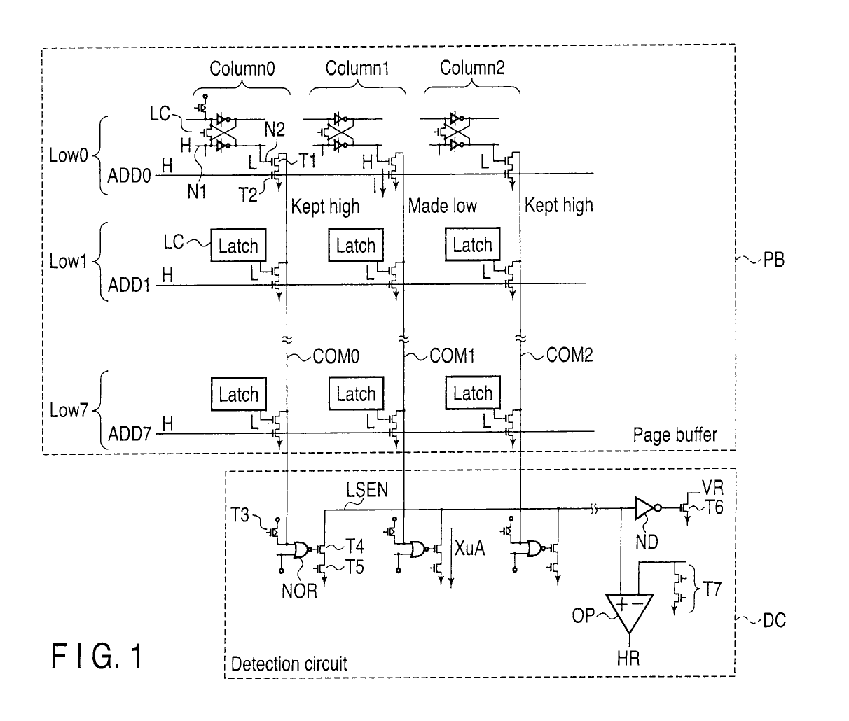

FIG. 1 schematically shows a page buffer, a detection circuit, and batch detection. As shown in FIG. 1, a page buffer PB comprises latches LC. Each of latches LC comprises a flip-flop circuit, and belongs to a specific column and row. One set of ends of all latches LC belonging to a column 0 are connected to a gate of an n-type metal oxide semiconductor field effect transistor (MOSFET) T1. One end of each transistor T1 is connected to a line COM0, and the other end is grounded through a transistor T2. Similarly, one set of ends of all latches LC belonging to a column x (x being a natural number) are connected to a gate of a corresponding transistor T1. The transistor T1 is connected to a line COMx at one end of its current pathway, and grounded at the other end through a corresponding transistor T2.

Each column comprises eight latches LC. A signal ADD0 is supplied to a gate of each transistor T2 belonging to a row 0. Similarly, signals ADD1 to ADD7 are supplied to the gates of the transistors T2 belonging to rows 1 to 7.

In a detection circuit DC, a line COM0 is connected to a power supply through a p-type MOSFET transistor T3, and is connected to a first input of a NOR gate NOR. The low-level signal is supplied to a second input of the NOR gate. An output of the NOR gate is connected to a gate of an n-type MOSFET transistor T4. The transistor T4 is connected to a line LSEN at one end of its current pathway, and is grounded at the other end through an n-type MOSFET transistor T5.

Similarly, the line COMx is connected to a corresponding set of the transistors T3, T4 and T5 and NOR gates for the column x, which are connected similarly to the set of the transistors T3, T4 and T5 and NOR gates for the column 0. In each column, the other end of the transistor T4 is commonly connected to the line LSEN.

The line LSEN is connected to a gate of an n-type MOSFET transistor T6 through a NAND gate ND. One end of the current pathway of the transistor T6 is detected as a potential VR, and the other end is grounded. The line LSEN is connected to a noninverted input of an operational amplifier OP. The noninverted input of the operational amplifier OP is connected to a predetermined number of series-connected n-type MOSFET transistors T7. The output of the operational amplifier OP is detected as a potential HR.

In batch detection, first, to-be-verified data is latched at the node N1 of each latch LC of the page buffer PB. When a memory cell has a target threshold, corresponding to-be-verified data is at the “H” level. When a memory cell does not have a target threshold, to-be-verified data is at the “L” level. The example shown in FIG. 1 assumes that the latch LC belonging to the column 1 and row 0 holds low to-be-verified data. Therefore, the transistor T1 connected to this latch LC is on.

All lines COMx and line LSEN are pre-charged high, and then the signals ADD0 to ADD7 are made high. Then, the potential of the line COM1 is decreased by a current I flowing through the transistors T1 and T2 connected to the latch LC holding fail to-be-verified data. On the other hand, the line COMx connected to the latch LC holding pass to-be-verified data is kept high.

The decreased potential of the line COM1 makes the output of the NOR gate connected to the line COM1 high. The potential of the line LSEN is then decreased by a current XuA flowing through the transistors T4 and T5 of the column 1. This decreasment in potential makes the potential VR low, which indicates the batch detection is a fail. On the other hand, if all to-be-verified data is high, potential of no line COMx decreases when the signals ADD0 to ADD7 are made high. Therefore, the potential of the line LSEN does not decrease, and the potential VR is kept high. As the high potential VR is detected, batch detection is determined to be a pass.

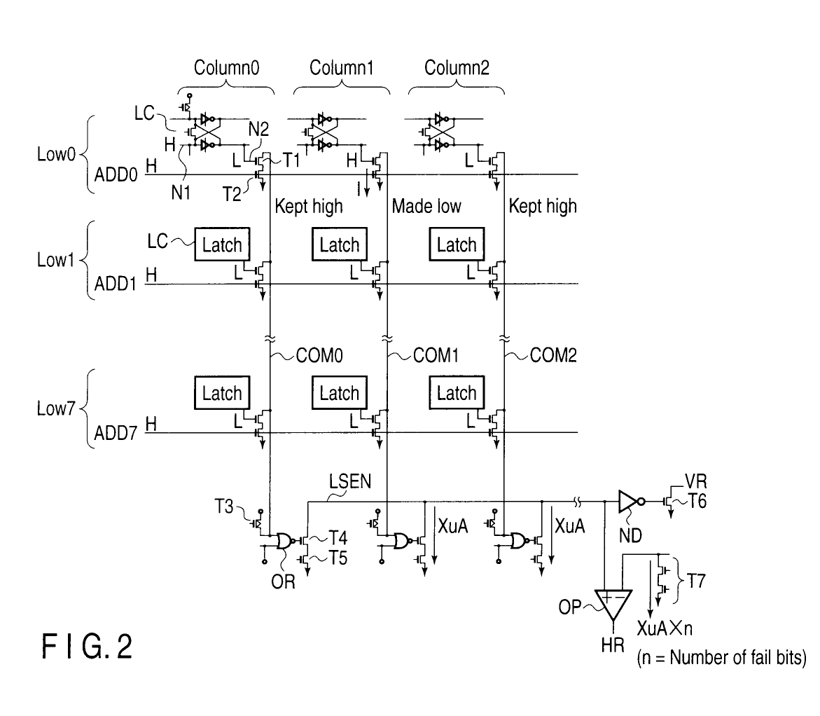

A fail bit counting is now described with reference to FIG. 2. The circuit configuration is the same as that in FIG. 1.

First, as in FIG. 1, to-be-verified data is read to each latch LC, all lines COMx and line LSEN are pre-charged high. The signal ADD0 is made high. The line COMx corresponding to the column of the latch LC holding pass to-be-verified data is kept high. On the other hand, the potential of the line COM1 belonging to the column of the latch LC holding fail to-be-verified data (e.g., the column 1) decreases.

The line LSEN is kept high if no to-be-verified data of the row 0 have fail bits, and its potential decreases if any of the to-be-verified data piece has a fail bit. The amount of potential decrease is equal to the potential corresponding to the number of fail bits in all to-be-verified data pieces. Therefore, the potential HR of the line LSEN is kept high when the count of fail bits (, which is defined by the number of transistors T7) is smaller than a predetermined number and is made low when the count exceeds the predetermined number through a potential change on the line LSEN. The result is processed by a logic circuit (not shown).

Then, the signal ADD1, which is next to the signal ADD0, is selected, and the same operations as those for the row 0 are repeated for the row 1. Further, the same operations are repeated for the rows 2 to 7, and the count of previous fail bits are counted up. The total number of counted fail bits is equal to the number of fail bits included in to-be-verified data of the same size as a page. When the accumulated count of fail bits exceeds a threshold (, or criteria), the fail bit counting is determined to be a fail. When the count does not exceed the threshold, the fail bit counting is determined to be a pass.

The above described detection circuit necessary for verification increases a chip area in an NAND flash memory.

Hereinafter, embodiments configured based on the findings will be described with reference to the accompanying drawings. In the following explanation, the components having substantially the same structures and functions are referred to with the same reference number, and are described only when necessary. Each embodiment exemplifies a device and method of embodying technical idea, and does not specify the material, shape, structure, and arrangement of components. The technical idea of each embodiment can be modified within the scope of the appended claims.

Each functional block may be implemented as hardware, computer software, or combination of the both. In order to clearly illustrate this interchangeability of hardware and software, descriptions will be made in terms of their functionality in general. Whether such functionality is implemented as hardware or software depends on the particular application and design constraints imposed on the overall system. Those of skilled in the art may implement the functionality in varying ways for each particular application, but any implementation approach is included in the scope of the embodiments. A specific functional block may be included in another function block, or implemented by another function block.

### First Embodiment

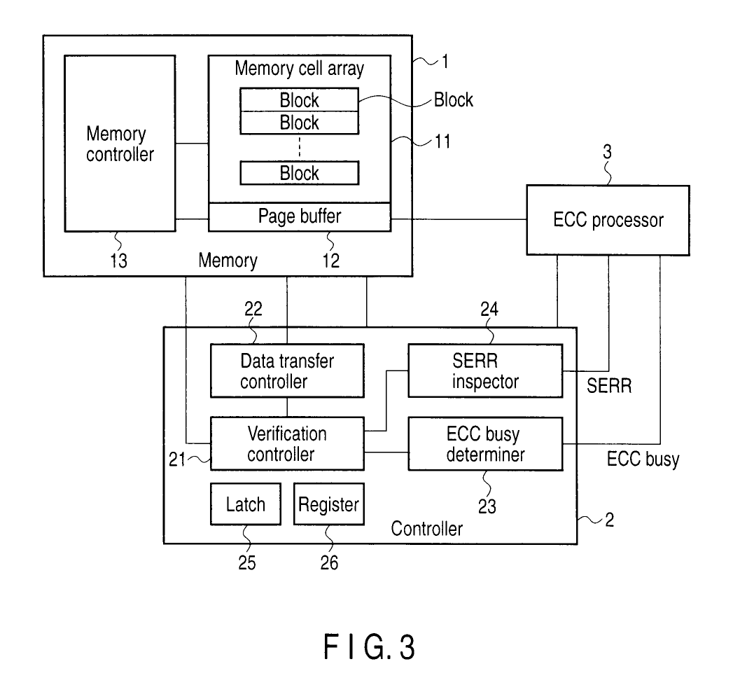

FIG. 3 is a schematic block diagram of a semiconductor memory device according to a first embodiment. As shown in FIG. 3, a semiconductor memory device includes a memory 1, a controller 2, and an ECC processor 3.

The memory 1 includes a memory cell array 11, a page buffer 12, and a memory controller 13. The memory 1 may be a NAND flash memory, for example, which is configured to read and write data from and to any selected page, and to erase data of any selected block. The memory cell array 11 includes blocks. Each block includes memory cells, word lines, and bit lines. A block includes pages consisting of memory cells. Memory cell transistors in each block are collectively erased.

Operations of the memory 1 are controlled by the memory controller 13. The memory controller 13 has functions necessary for various operations, and includes a bit line control circuit, a word line control circuit, and a voltage generation circuit, for example. The memory controller 13 receives various commands for controlling the memory 1 and addresses, and outputs the received data, through data input/output terminals. When the memory controller 13 receives a write command, an address signal, and write data, the write data is supplied to the memory cell array 11. The memory controller 13 applies a necessary voltage to the word line specified by the address signal. When a read command and an address signal are received, the memory controller 13 applies a predetermined potential to the bit line specified by the address signal and other control lines, and reads data from the specified memory cells. The read data is read by the page buffer 12, amplified by a sense amplifier under control of the memory controller, and output to the outside of the memory 1. When an erase command and an address signal are received, the memory controller 13 applies a predetermined potential to word lines specified by the address signal and other predetermined positions, and erases data in the specified memory cells.

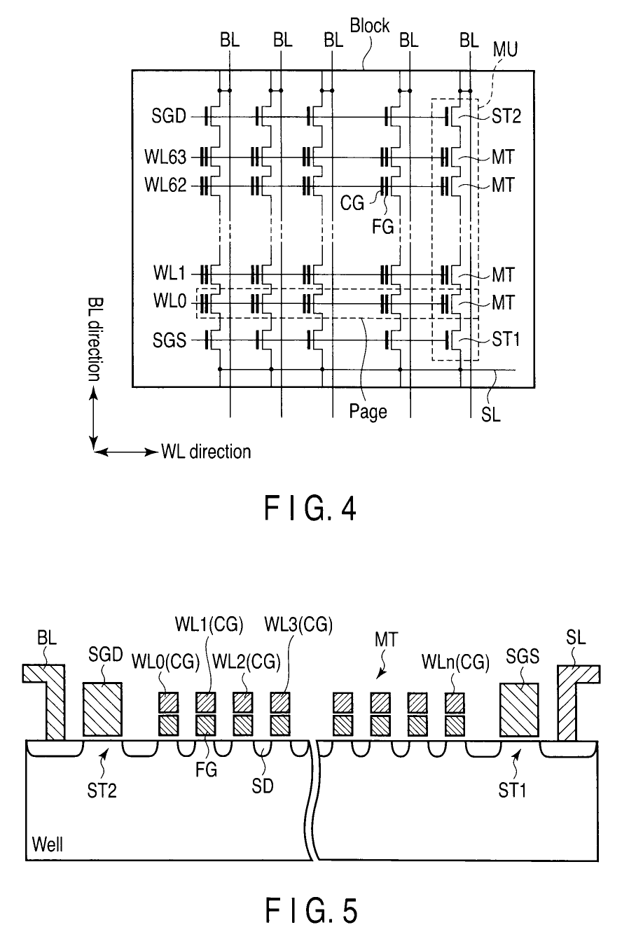

FIG. 4 is a circuit diagram of a specific example of a block. FIG. 5 is a sectional view of a block. As shown in FIG. 4 and FIG. 5, a block includes memory cell columns MU. A memory cell column MU includes a NAND string, and select transistors ST1 and ST2. A NAND string includes series-connected memory cell transistors MT. The select transistors ST1 and ST2 are connected to both ends of the NAND string, respectively. The other end of the current pathway of the select transistor ST2 is connected to a bit line BL, and the other end of the select transistor ST1 is connected to a source line SL.

Word lines WL0 to WL63 are connected to the memory cell transistors MT belonging to the same row. A select gate line SGD is connected to all select transistors ST2 in the block. The select gate line DGS extends along the WL direction, and is connected to all select transistors ST1 in the block. The memory cell transistors MT connected to the same word line WL constitute one page. Data reading and writing are performed in units of pages. If a memory cell is capable of holding multibit data, more than one pages is assigned to one word line.

A memory cell MT is provided at each intersection of a bit line BL and a word line WL. A memory cell MT is provided on a well formed in a semiconductor substrate. The well is connected to a voltage generation circuit, from which it receives a predetermined voltage. A memory cell MT includes a tunnel insulating film formed on the well (not shown), a floating electrode FG as a charge trapping layer, a gate insulating film (not shown), a control electrode CG (, or a word line WL), and source/drain areas SD. A source/drain as part of a current pathway is serially connected to a source/drain of the adjacent memory cell MT. The select transistors ST1 and ST2 include a gate insulating film formed on a semiconductor substrate (not shown), and gate electrodes SGS and SGD, and source/drain areas SD.

The ECC processor 3 receives data from the page buffer 12 when reading data, and corrects one or more errors in the received data. As codes used for ECC, linear codes such as the BCH code, the RS code, and the hamming code may be used. In the error correction using these codes, a parity is generated for data when coding, and “data+parity” is used as a code for ECC. As a nature of such a code, when data only consists of “0” bits, its parity also only consists of “0” bits. In other words, a parity only consisting of “0” bits is legal as a correct code, and when decoding, several fail bits can be correctly decoded through such a parity within the correction capacity of ECC. The ECC processor 3 operates also for verification. The ECC operation for verification will be described in detail later.

The controller 2 controls the memory 1 and ECC processor 3. The controller 2 includes a verify controller 21, a data transfer controller 22, an ECC busy determiner 23, a SERR inspector 24, a latch 25, and a register 26, as components for executing the functions for verification. The verify controller 21 controls entire processes of verification, and controls the memory 1 and ECC controller 3 in verify operation. The verify controller 21 communicates with the data transfer controller 22, ECC busy determiner 23, SERR inspector 24, latch 25, and register 26, and controls them for verification. The operations of the verify controller 21, data transfer controller 22, ECC busy determiner 23, and SERR inspector 24 will be described in detail later. The latch 25 and register 26 are used in the following embodiments, and described with reference to these embodiments.

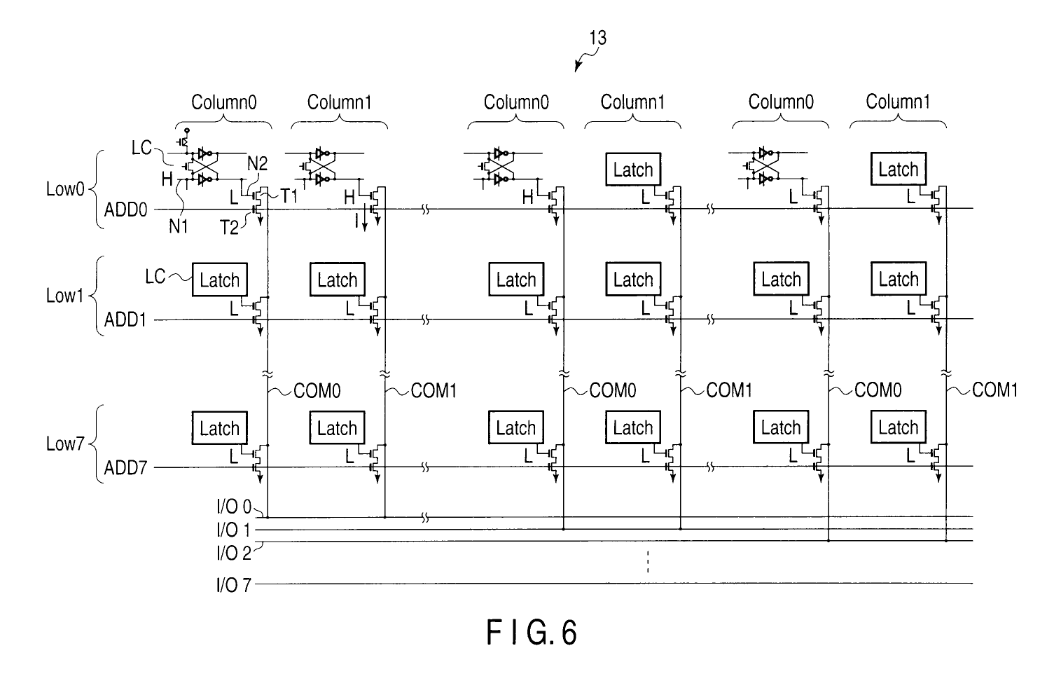

FIG. 6 schematically illustrates the circuit configuration of the semiconductor memory device according to a first embodiment. As shown in FIG. 6, the page buffer 12 includes latches LC, and is configured to hold data of one page. A specific number of specific latches form a specific group. For example, one column includes a specific number of latches, and columns having the same configuration are provided. One row includes a specific number of latches, and rows having the same configuration are provided. The following description assumes that a column and row include such a specific number of latches; however latches only need to constitute a specific group logically, and do not necessarily need to be arranged in rows and columns physically also.

Latches LC have the same configuration, and each includes a flip-flop circuit. Specifically, a latch LC includes two NAND gates, and the output and input of one NAND gate are connected to the input and output of the other NAND gate, respectively. An n-type MOSFET is connected between the inputs of two NAND gates. An input N1 of one NAND gate is connected to a corresponding memory cell, as an input to a latch LC.

In FIG. 6, the output node N2 of each latch LC in the leftmost column 0 is connected to the gate of the n-type MOSFET transistor T1. Each transistor T1 is grounded through a corresponding transistor T2 at one end of its current pathway, and is commonly connected to the line COM0 at its other end. Similarly, the output N2 of the latch LC of the column n (n being a natural number) is connected to the gate of a corresponding transistor T1 for the column n. In the column n, each transistor T1 is grounded through a corresponding transistor T2 at one end of its current pathway, and is commonly connected to the line COMn at its other end.

A set of adjacent lines COMn of the predetermined number (m) are connected to the same one of I/O lines. The I/O lines include, for example, eight lines I/O 0 to I/O 7. In particular, the lines COMn of columns 0 to m are connected to the I/O line 0, and the lines COMn of column m+1 to 2m are connected to the I/O line 1. The remaining lines COMn are connected based on the analogous rule. The following description assumes that column numbers are assigned to each set of columns m. In particular, the column 0 is the smallest number column connected to each of the I/O lines 0 to 7, and the column m is the highest number column. Therefore, eight of column 0 are present, and eight of column 1 are also present. The same is true for the other columns. The I/O lines 0 to 7 are connected to the ECC processor 3 through the bus between the page buffer 12 and ECC processor 3. In the following description, I/O lines 0 to 7 are representatively referred to as an I/O line unless they need to be separately referred to.

The gate of each transistor T2 connected to each latch of the row 0 is commonly connected to the address signal ADD0. Similarly, the address signals ADD1 to ADD7 are supplied to the gates of the transistors T2 connected to the latches of the rows 1 to 7. The address signals ADD0 to ADD7 are connected to the controller 2.

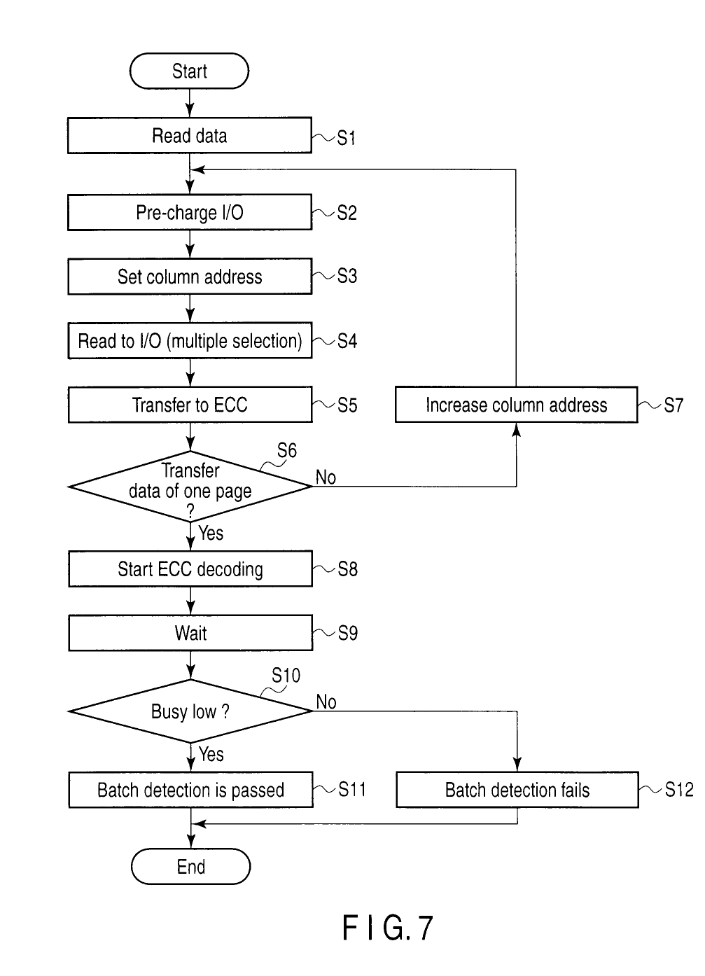

The verification of the semiconductor memory device according to the first embodiment will now be described with reference to FIG. 7. The first embodiment concerns batch detection as an example of verification. FIG. 7 is a schematic flowchart of verification (in particular, batch detection) by the semiconductor memory device according to the first embodiment.

As described above, the ECC processor 3 can correctly detect an error in data consisting of only “0” bits. Therefore, the ECC processor 3 can correctly detect an error in data consisting of only “1” bits if it receives such data with all bits inverted. An expected value of all bits of to-be-verified data is “1”. Therefore, supplying all-bits-inverted to-be-verified data with the ECC processor 3 allows for verifying to-be-verified data and counting fail bits in it.

Thus, after pieces of to-be-verified data are sequentially input to the ECC processor 3 through an internal data bus, a syndrome is sequentially generated in the ECC processor 3, and data of the same length as the code length of ECC (usually, defined as a sector) is input, then a syndrome can be defined. Then, the ECC processor 3 decodes the thus generated data, and outputs the count and address of errors according to the result of decoding.

Verification only requires determination of whether an error is present, and a range of batch detection is to-be-verified data of the same size as a page, and therefore it is necessary to determine whether an error is present in one page. The time taken to execute such operation is roughly estimated as follows. The following parameter is assumed. One page consists of eight sectors, the page size is 4 kB (actually 4 kB+128B including a redundant area), and the sector size is 512B+redundant area 16 B=526 B. Generally, an ECC circuit (including the ECC processor 3) ECC-processes received data in units of sectors. Therefore, a series of operations including transfer of data of one sector to the ECC circuit, computation in the ECC circuit, and determination of the count of errors, is repeated for eight sectors, which allows for error detection in to-be-verified data of eight sectors, thus batch detection by the ECC processor 3. For example, assume that a bus between the page buffer 12 and ECC processor 3 has a 32-bit width, transfer of one sector data (528 B) requires 132 cycles, transfer of data of the same size as one page (eight sectors) requires 132×8=1056 cycles. Also assume data transfer in one clock period of 20 ns (, or 50 MHz frequency), the whole data transfer requires 20 μs or more. Since batch detection is executed whenever verification is needed for writing and erasing, one verification for such long time such as several microseconds degrades a flash memory in performance.

In this embodiment, to-be-verified data in the form with multiple addresses selected simultaneously, or AND of data for multiple addresses, is read to the internal data bus. Detailed operations will be described hereinafter.

Upon start of verification, the verify controller 21 causes the memory 1 to read to-be-verified data from object memory cells to the page buffer 12 (step S1). To-be-verified data is held at the input node N1 of each latch LC. To-be-verified data is logical high when a corresponding memory cell passes verification, and logical low if not (verification fail).

Next, the verify controller 21 pre-charges the I/O lines 0 to 7 high (step S2). The verify controller 21 selects all (i.e., eight in this example) columns 0, and selects all address signals ADD0 to ADD7 (step S3). As a result, in each column 0, to-be-verified data is output to a corresponding one of the I/O lines 0 to 7 in the form of wired OR (step S4). In other words, the to-be-verified data held in all latches LC of each column 0 connected to the I/O lines 0 to 7 is read to the corresponding one of the I/O lines 0 to 7 in the reduced form. For example, assume that all latches LC of the column 0 connected to the I/O line 0 hold data indicative of verification pass (i.e., the potential at the node N1 is low), then the I/O line 0 is kept high. On the other hand, as the column 0 connected to, e.g., the I/O line 1 includes one latch LC that holds data indicative verification fail, the I/O line 1 is made low.

The data transfer controller 22 then transfers the data that has been read to the I/O lines 0 to 7 by selecting multiple addresses to the ECC processor 3 (step S5). All-bits-inverted version of to-be-verified data is supplied to the ECC processor 3. For inverting all bits of to-be-verified data, one or more inverter may be provided between the page buffer 12 and ECC processor 3 to invert all bits of data transferred to the ECC processor 3 upon verification by a command received from the data transfer controller 22.

The verify controller 21 then determines whether to-be-verified data of the same size as a page (528 bytes, for example) has been transferred to the ECC processor 3 (step S6). If not, a column address is incremented by one (step S7), and steps S2 to S6 are repeated. Since to-be-verified data is selected by simultaneously selecting eight addresses and read, time taken to transfer one-page-size to-be-verified data is equal to 132 cycles (approximately 2.6 μs). Therefore, in this example, the determination in step S6 is equivalent to determination of whether steps S2 to S5 are repeated by 132 times. The size of to-be-verified data thus transferred to the ECC processor is equal to a sector of the ECC processor 3 (the ECC processing unit).

The verify controller 21 then instructs the ECC processor 3 to ECC-process (, or ECC decoding) the received data. Receiving the instruction, the ECC processor 3 ECC-processes the data (step S8). In particular, the ECC processor 3 generates a syndrome from the supplied to-be-verified data, decodes the generated syndrome, and detects the count and address of errors included in the to-be-verified data. The ECC processor 3 keeps outputting a busy signal during the operation, and outputs an SERR after completion of the operation. The busy signal and SERR are supplied to the ECC busy determiner 23 and SERR inspector 24, respectively. The time taken to complete the ECC processing and SERR output is generally several hundred cycles for the ECC processor with a multibit error-correcting capability. However, only several cycles (5 cycles, for example) of these several hundred cycles are required to detect an error (, or to define a fail state). Therefore, if the busy signal is low after a lapse of the time taken to define a fail state (5 cycles, for example), this means that to-be-verified data includes no fail bit. Thus, the busy determiner 23 waits for such time (5 cycles, for example) required by the ECC processor 3 to determine whether an error is present (step S9).

After such waiting, the ECC busy determiner 23 determines whether the busy signal is low (step S10). When the busy signal is low, this means that all bits of the to-be-verified data pass the verification, and the verify controller 21 determines that the batch detection is passed (step S11), and the verification is terminated. On the other hand, if the ECC busy signal is high in step S10, the to-be-verified data includes at least one fail bit, and the controller 4 determines that the batch detection fails (step S12), and the verification is terminated.

As described above, according to the first embodiment, the ECC processor determines a pass/fail of verification. A flash memory is usually provided with an ECC processor, and utilizing it for verification eliminates a need for a detection circuit dedicated to verification. Therefore, the chip area can be reduced by the area that would be taken for the detection circuit dedicated to verification.

As described above, since page-size data is equivalent to data of the same size as eight sectors, data pieces of eight sectors need to be sequentially transferred for batch detection over page-size data. On the other hand, according to the first embodiment, data of eight row addresses wired-ORed can be read on the internal data bus by selecting eight addresses. As a result, a data transfer cycle is reduced to ⅛. In other words, data of substantially the same as a page (i.e., eight sectors) can be transferred to the ECC processor 3 within a transfer cycle of one sector. This prevents an increase of time taken for verification from the technique that uses an exclusive detection circuit.

Further, since data is wired-ORed, a plurality of fail bits may be included in a plurality of bits reduced by the wired OR. However, the purpose of batch detection is to detect at least one fail bit in page-size to-be-verified data, and can be achieved by the embodiment. Further, since the ECC processor 3 is supplied with data in units of sectors, which is the same as its processing unit, ECC processor 3 can execute the processing without taking additional measures. Actually, the embodiment is easily applied to the case where the size of to-be-verified data smaller than a sector is input to the ECC processor 3 because an expected value of all bits of to-be-verified data is “1” and the ECC processor 3 is supplied with to-be-verified data with all bits inverted, and, based on this, shortage of data received by the ECC processor can be compensated. In particular, the ECC processor 3 operates with assumption that it receives a “0” bit in place with non-existing bit to make a full sector. A specific example for this point will be described with reference to the following embodiments.

### Second Embodiment

A second embodiment relates to verification that involves counting the number of fail bits in to-be-verified data of the same size as a page (referred to as a full-page bit scan).

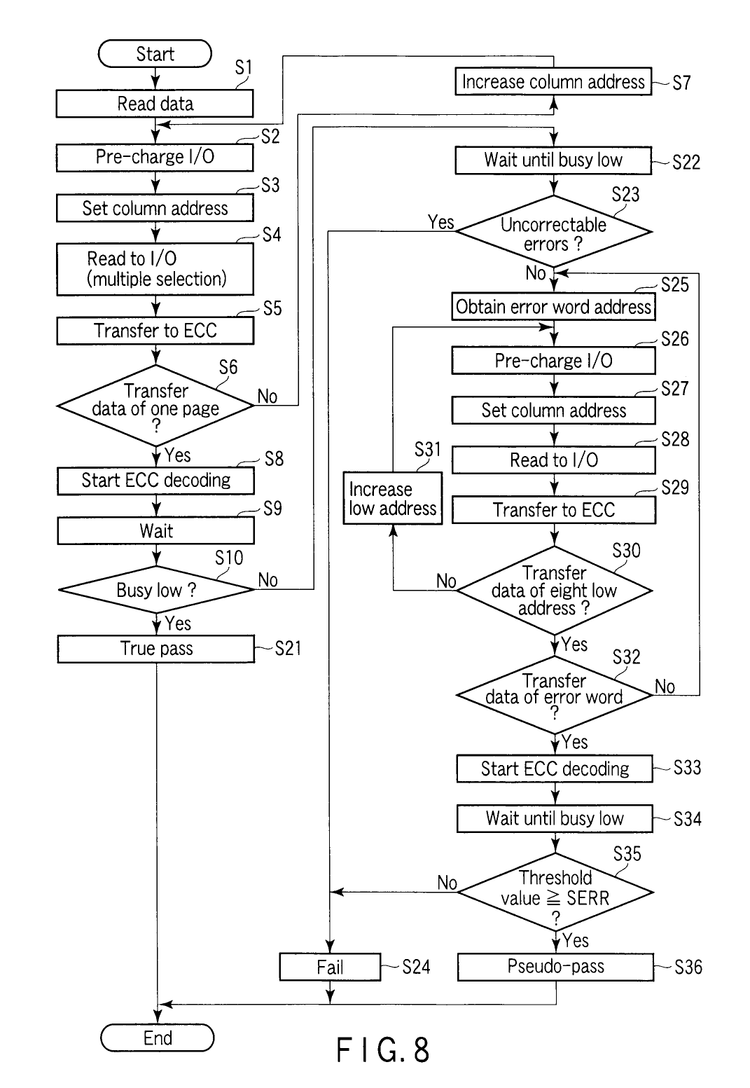

The components of the semiconductor memory device according to the second embodiment are the same as those of the first embodiment (FIGS. 3 to 6). Operation of the second embodiment will be described with reference to FIG. 8. FIG. 8 is a schematic flowchart of verification (in particular, full-page bit scan) by a semiconductor memory device according to the second embodiment. The general flow is as follows. First, batch detection is performed as in the first embodiment. When batch detection fails, a pseudo-pass is determined depending on whether the count of fail bits is smaller than an allowable level. The detailed operation will now be described.

As shown in FIG. 8, first, steps S1 to S10 are executed. In particular, page-size to-be-verified data is transferred to the ECC processor 3 by selecting multiple addresses, and is ECC-processed. When an ECC busy signal is low in step S10, it means that the page-size to-be-verified data under processing includes no fail bit. The verify controller 21 determines the full-page bit scan to be a true pass (step S21), and the verification is terminated. If the ECC busy signal is high in step S10, the verify controller 21 waits until the ECC processor 3 completes its operation and the ECC busy signal transitions to low (step S22) in order to start counting fail bits.

The SERR inspector 24 then receives a SERR from the ECC processor 3. When the to-be-verified data includes the count of errors exceeding the correction capability of the ECC processor 3, a SERR includes information indicating that the errors are uncorrectable, otherwise data indicative of the count of errors and the addresses of words including the errors are output as ADDRESS to the controller 2. A word means the size of data transferred to the ECC processor 3 by one cycle. Therefore, as in this example, for the case of the to-be-verified data transferred by one cycle being 32 bits, the size of one word is 32 bits.

The SERR inspector 24 checks the SERR, and determines whether the to-be-verified data includes the count of errors exceeding the correction capability of the ECC processor 3 (step S23). When the count of errors exceeds the correction capability, it means that the number of fail bits in the to-be-verified data cannot be counted. Thus, the verify controller 21 determines the verification (i.e., full-page bit scan) to be a fail (step S24), and the verification is terminated.

When the to-be-verified data includes the count of errors not exceeding the correction capability in step S23, the SERR inspector 24 checks a SERR, extracts one or more addresses of a word including an error, and holds it in the latch 25 (step S25). As described above, the to-be-verified data specified by one word address may include more than one fail bits due to selection of multiple addresses. Therefore, the to-be-verified data specified by a specific word address is then checked without multiple addresses selection. The outline is similar to steps S2 to S20, except the details such as to-be-verified data being read for each row address without selecting multiple row addresses. The detailed operation is as follows.

First, the verify controller 21 pre-charges the I/O lines 0 to 7 high (step S26). Then, the verify controller 21 selects one or more columns corresponding to one word address determined to have an error, and selects the address signal ADD0 (step S27). As a result, in each selected column, the to-be-verified data held in latch LC at the row address 0 is read to the corresponding I/O line I/O (step S28). Then, the data transfer controller 22 transfers the to-be-verified data read to the I/O line I/O to the ECC processor 3 (step S29). The verify controller 21 then determines whether the to-be-verified data of eight row addresses corresponding to the word under processing has been transferred to the ECC processor 3 (step S30). If the to-be-verified data of any one of the row addresses has not been transferred, the row address is incremented by one (step S31), and steps S26 to S29 are repeated. In this way, the to-be-verified data of one word is transferred without selecting multiple addresses. Thus, each bit of the to-be-verified data transferred to the ECC processor reflects to-be-verified data held in only one latch.

After the to-be-verified data of one word is transferred, the verify controller 21 determines whether the to-be-verified data of all word addresses determined to have an error has been transferred (step S32). If to-be-verified data of any one of the row addresses has not been transferred, this word address is latched (step S25), and steps S26 to S31 are repeated for the word address. For example, when there are four error-containing words, steps S25 to S31 are repeated by four times.

After the error-containing data of all word addresses is transferred, the verify controller 21 instructs the ECC processor 3 to ECC-process the received data. Receiving the instruction, the ECC processor 3 starts ECC processing (step S33). The size of the data transferred to the ECC processor 3 is smaller than one sector. In example, for a case of SERR indicating that one bit error is present, the data transferred in steps S25 to S32 is equal to 32 (bit/1 transfer cycle)×8 (expanded addresses ADD0 to ADD7)=256 bits=32 B. This number is smaller than one sector (528 B). However, since an expected value of all bits of to-be-verified data is “1” as described above, the ECC processor 3 is supplied with to-be-verified data with all bits inverted, and shortage of data is compensated. In particular, the ECC processor 3 performs operation with assumption that a “0” bit is received to compensate shortage to one sector. Then, the verify controller 21 instructs the ECC processor 3 to ECC-process the received data. Receiving the instruction, the ECC processor 3 ECC-processes the received data.

The ECC busy determiner 23 monitors an ECC busy signal, and waits until the ECC busy signal transitions to low (step S34). After ECC processing is completed, the SERR inspector 24 receives a SERR from the ECC processor 3. The SERR inspector 24 then determines whether the count of errors indicated by the SERR is smaller than a predetermined threshold (step S35). When the count of errors is smaller than the threshold, the verify controller 21 determines the full-page bit scan to be a pseudo-pass (step S36), and the verification is terminated. When the count of errors exceeds the threshold, the verify controller 21 determines the full-page scan to be a fail (step S24), and the verification is terminated. The threshold used in step S35 is selected based on the number of fail bits allowed in page-size to-be-verified.

As described above, in the second embodiment, the ECC processor determines a pass/fail of verification as in the first embodiment. Therefore, the second embodiment provides the same advantages as those of the first embodiment. Further, in the second embodiment, when a fail bit is detected after batch detection for page-size to-be-verified data, verification is done for to-be-verified data of each row address only for the corresponding one or more word addresses. Therefore, full-page bit scan using the ECC processor 3 is possible.

### Third Embodiment

A third embodiment relates to verification and rewriting based on the result of the verification.

A series of steps for data writing includes verification and rewriting data to memory cells determined to be a verification fail. Verification is re-executed after rewriting, and rewriting is re-executed after the re-verification. In this way, verification and rewriting are repeated. However, the time available for rewriting is limited, and an upper limit is usually set for the count of rewriting. The third embodiment relates to verification and rewriting considering the upper limit for the count of rewriting.

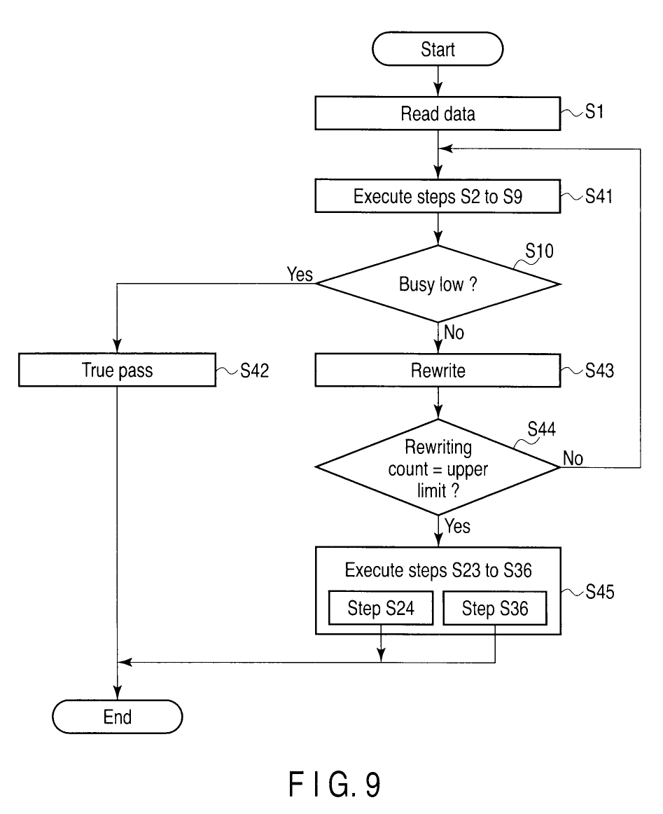

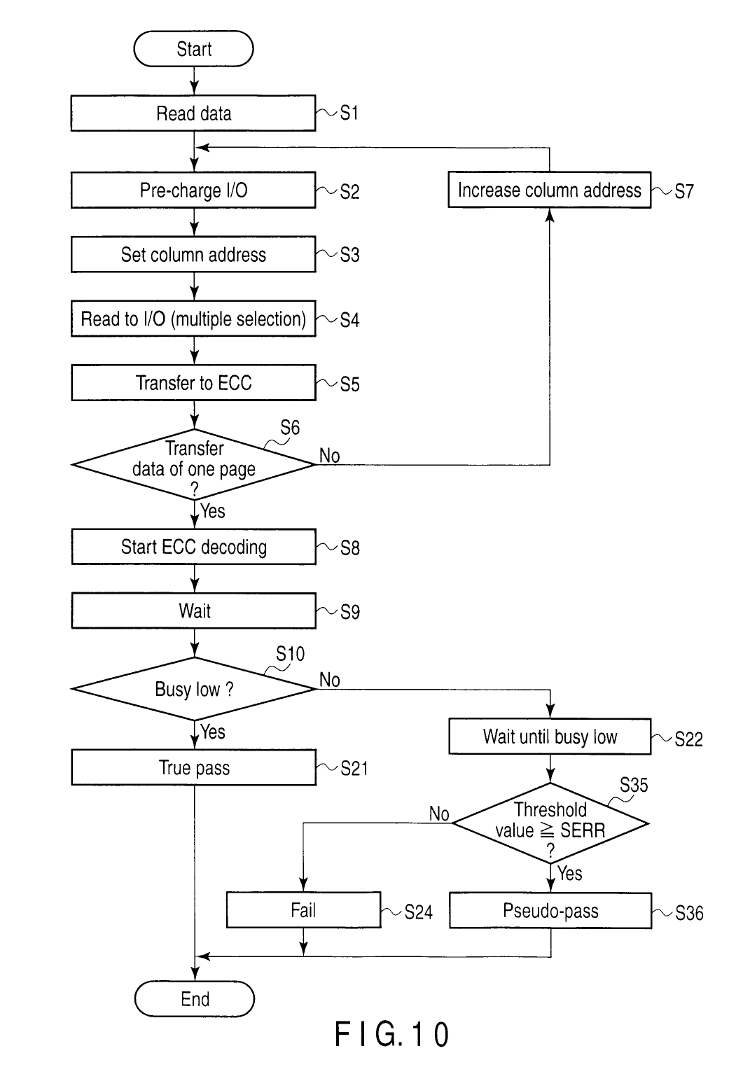

The components of the semiconductor memory device according to the third embodiment are the same as those of the first embodiment (FIGS. 3 to 6). Operation of the third embodiment will be described with reference to FIG. 9. FIG. 9 is a schematic flowchart of verification and rewriting by a semiconductor memory device according to the third embodiment.

As shown in FIG. 9, first, to-be-verified data is read (step S1). Then, steps S2 to S9 of the first embodiment (FIG. 7) are executed as step S41. In particular, page-size to-be-verified data is transferred to the ECC processor 3 by selecting multiple addresses, and is ECC-processed. When the ECC busy signal is low in step S10, the verify controller 21 determines the verification to be a true pass (step S42), and the verification is terminated. If the ECC busy signal is high in step S10, the verify controller 21 instructs the memory 1 to rewrite data to object memory cells (, or page) in the memory 1. Receiving the instruction, the memory cell 1 rewrites data (step S43).

The verify controller 21 then determines whether the count of already executed rewriting has reached a predetermined upper limit (step S44). When the upper limit count is not reached, step S41 is executed. Then, steps S41 to S44 are repeated until the ECC busy signal transitions to low in step S10, or the count of past rewriting reaches the upper limit in step S44.

When the count of writing reaches the upper limit in step S44, steps S23 to S36 of the second embodiment (FIG. 8) are executed as step S45. In particular, to-be-verified data is transferred without selecting multiple addresses, and the number of fail bits is counted. In the third embodiment, steps S24 and S36 are continued to the end block in FIG. 9.

As described above, in the third embodiment, the ECC processor determines a pass/fail of verification as in the first embodiment. Therefore, the third embodiment provides the same advantages as those of the first embodiment. Further, by including the same steps as those of the second embodiment, the third embodiment provides the same advantages as those of the second embodiment.

Further, in the third embodiment, the batch detection and rewriting of the first embodiment are repeated until the count of rewriting reaches an upper limit, and after reaching the upper limit number, the full-page bit scan of the second embodiment is executed. In particular, rewriting is repeated up to the upper limit until no fail bit is detected by the batch detection, and after reaching the upper limit number, when the count of fail bits is smaller than a predetermined level (for example, in the range of correction capability of the ECC processor), verification is determined to be a pseudo-pass. Thus, rewriting is repeated up to the upper limit until no fail bit is detected, and after reaching the upper limit number, a predetermined number of fail bits is permitted. Selecting an appropriate rewriting upper-limit can observe allowable writing time. In sum, combining the first and second embodiments can execute verification and rewriting effectively while observing the allowable writing time.

### Fourth Embodiment

A fourth embodiment relates to verification for counting the bytes including a fail bit in page-size to-be-verified data (referred to as a full-page byte scan).

The components of the semiconductor memory device according to the fourth embodiment are the same as those of the first embodiment (FIGS. 3 to 6). Operation of the fourth embodiment will be described with reference to FIG. 10. FIG. 10 is a schematic flowchart of verification (in particular, full-page byte scan) by the semiconductor memory device according to the fourth embodiment. The general flow is as follows. First, batch detection is performed as in the first embodiment. When the batch detection fails, a pseudo-pass is determined depending on whether the count of bytes including a fail bit is smaller than an allowable level. The detailed operation will now be described.

As shown in FIG. 10, steps S1 to S10 are executed. In particular, page-size to-be-verified data is transferred to the ECC processor 3 by selecting multiple addresses, and ECC-processed. When the ECC busy signal is low in step S10, it means that the page-size to-be-verified data under processing includes no fail bit. The verify controller 21 determines the full-page byte scan to be a true pass (step S21), and the verification is terminated. If the ECC busy signal is high in step S10, the verify controller 21 waits until the ECC processor 3 completes its operation and the ECC busy signal transitions to low (step S22) in order to start counting bytes including a fail bit.

The SERR inspector 24 then determines whether the count of errors indicated by the SERR is smaller than a threshold (step S35). In the fourth embodiment, as in the first embodiment, to-be-verified data of eight row addresses is reduced to one to-be-verified data piece. Thus, the information indicated by the SERR exactly corresponds to the information indicating whether each byte includes at least one fail bit. By comparing the SERR with the threshold, the count of fail-bit-containing bytes can be compared with the threshold. The threshold used in step S35 is selected based on the number of fail-bit-containing bytes allowed in page-size to-be-verified data.

When the count of errors is smaller than the threshold in step S35, the verify controller 21 determines the full-page byte scan to be a pseudo-pass (step S36), and the verification is terminated. If the count of errors is higher than the threshold, the verify controller 21 determines the full-pate byte scan to be a fail (step S24), and the verification is terminated.

As described above, in the fourth embodiment, the ECC processor determines a pass/fail of verification as in the first embodiment. Therefore, the fourth embodiment provides the same advantages as those of the first embodiment.

Further, in the fourth embodiment, it is possible to determine how many set of bits (i.e., bytes) of the same number of pieces of to-be-verified data reduced to one piece of to-be-verified data includes a fail bit. Such full-page byte scan can be completed in shorter time than full-page bit scan, and is convenient for the case where the presence or absence of a fail bit does not need to be so exactly determined as in full-page bit scan. For example, full-page byte scan is convenient for counting fail columns in a die sorting test, for example, to determine whether the number of fail columns is smaller than the number of redundant columns.

### Fifth Embodiment

A fifth embodiment relates to verification for counting fail bits in units of segments of a page (referred to as segment bit scan).

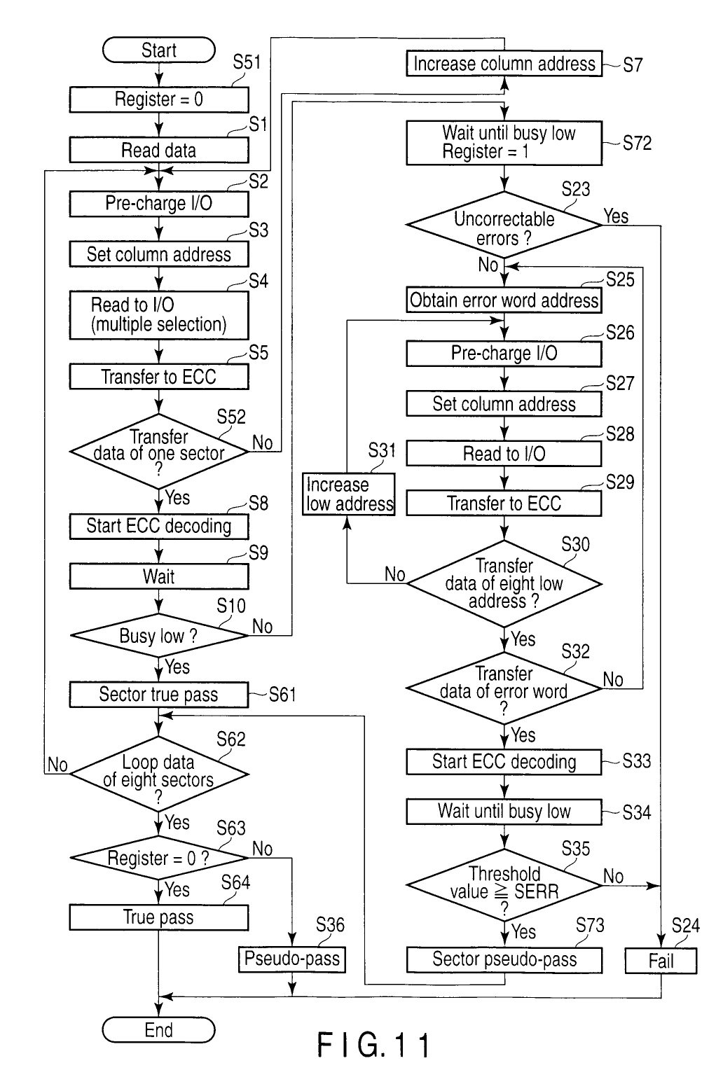

The components of the semiconductor memory device according to the fifth embodiment are the same as those of the first embodiment (FIGS. 3 to 6). Operation of the fifth embodiment will be described with reference to FIG. 11. FIG. 11 is a schematic flowchart of verification (in particular, segment bit scan) by the semiconductor memory device according to the fifth embodiment. The general flow is as follows. First, to-be-verified data is processed in a unit smaller than a page. When any of a predetermined number of to-be-verified data does not include a fail bit, verification is determined to be a pass. When to-be-verified data including a fail bit is detected, whether the to-be-verified data is a pseudo-pass is determined depending on the count of fail bits. The detailed operation will now be described.

As shown in FIG. 11, the verify controller 21 sets the register 26 holding a value for checking a true pass to “0” (step S51). Then, steps S1 to S5 are executed. In particular, to-be-verified data is transferred to the ECC processor 3 by selecting multiple addresses. The verify controller 21 then determines whether to-be-verified data of one sector (i.e., 544 bits) has been transferred to the ECC processor 3 (step S52). When the transferred to-be-verified data does not reach one sector, a column address is incremented by one (step S7), and steps S2 to S6 are repeated. Note that the transferred to-be-verified data takes the form in which data of eight row addresses are reduced to one to-be-verified data piece.

When to-be-verified data of one sector has been transferred in step S52, the verify controller starts ECC processing (step S8), waits (step S9), and determines whether an ECC busy signal is low (step S10). When the ECC busy signal is low in step S10, the sector-size to-be-verified data under processing includes no fail bit, and the verify controller 21 determines the to-be-verified data to be a true pass (step S61).

The verify controller 21 then determines whether a predetermined number of sector-size to-be-verified data pieces (8 sectors, for example) has been determined to be a true pass (step S62). If sector-size to-be-verified data remains to be unchecked for a true pass, the verify controller determines whether the next sector-size to-be-verified data is a true pass (steps S1 to S5, S62, S7 to S10, S61). When all sector-size to-be-verified data has been determined in step S62, the verify controller 21 determines whether the true pass check register 26 is at “0” (step S63). As described later, if any sector-size to-be-verified data includes a fail bit, then the true pass check register 26 is set to “1”. Therefore, when the register 26 is at “0”, it means that no sector-size to-be-verified data includes a fail bit, and the verify controller 21 determines the sector bit scan to be a true pass (step S64), and the verification is terminated.

When the ECC busy signal is high in step S10, the sector-size to-be-verified data under processing includes a fail bit. Whether the to-be-verified data is a pseudo-pass is then checked. In particular, first, the verify controller 21 waits until the ECC busy signal goes low, and sets the true pass check register 26 to “1” (step S72) for indicating that the segment bit scan may be a pseudo-pass, but is not a true pass, in the later determination.

The SERR inspector 24 then checks a SERR, and determines whether the sector-size to-be-verified data being processed includes the count of errors exceeding the correction capability (step S23). When the count of errors exceeds the correction capability, the verify controller 21 determines the verification (i.e., segment bit scan) to be a fail (step S24), and the verification is terminated. If the count of errors is smaller than the correction capability in step S23, steps S25 to S35 are executed. In particular, the sector-size to-be-verified data being processed is read without selecting multiple addresses, and whether the count of fail bits included in the to-be-verified data exceeds the threshold. Whether the sector is a pseudo-pass is then determined by counting the fail bits included in the to-be-verified data. The threshold used in step S35 is selected based on the number of fail bits allowed in sector-size to-be-verified data.

When the count of errors is smaller than the threshold in step S35, the verify controller 21 determines the to-be-verified data under processing to be a pseudo-pass (step S73). If the count of errors exceeds the threshold, the verify controller 21 determines the verification (i.e., segment bit scan) to be a fail (step S24), and the verification is terminated.

Step S73 is continued to steps S76 and S63. When reaching step S62 through step S73, the true pass check register 26 is usually at “1”. Thus, the verify controller 21 determines the verification (i.e., segment bit scan) to be a pseudo-pass (step S36), and the verification is terminated.

In the example described hereinbefore, the column address is incremented by one at a time. In this way, sector-size to-be-verified data consists of a set of to-be-verified data pieces consisting of to-be-verified data of serial column addresses. However, the column address may be incremented by two or more. For example, incrementing the column address by two generates sector-size to-be-verified data that consists of a set of to-be-verified data pieces of alternate column addresses. In this way, a sector having a desired configuration can be formed.

As described above, in the fifth embodiment, the ECC processor determines a pass/fail of verification as in the first embodiment. Therefore, the fifth embodiment provides the same advantages as those of the first embodiment.

Further, in the fifth embodiment, fail-bit detection and pseudo-pass determination based on the fail-bit count is executed in the unit that is equal to the processing unit of the ECC processor 3. Therefore, the embodiment can be used to improve the yield of the semiconductor memory devices at the time of D/S, for example.

### Sixth Embodiment

A sixth embodiment relates to verification for counting the count of bytes including a fail bit in units of segments of a page.

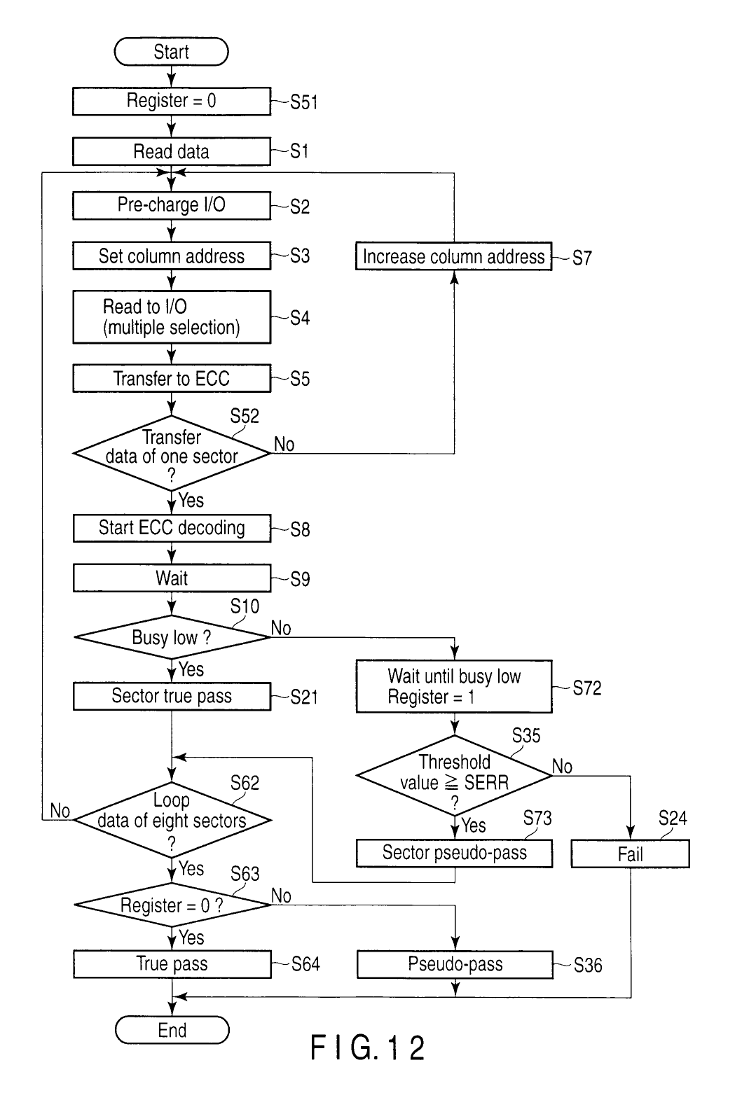

The components of the semiconductor memory device according to the sixth embodiment are the same as those of the first embodiment (FIGS. 3 to 6). Operation of the sixth embodiment will be described with reference to FIG. 12. FIG. 12 is a schematic flowchart of verification by a semiconductor memory device according to the sixth embodiment. The general flow is as follows. First, to-be-verified data is processed in a unit smaller than a page as in the fifth embodiment, and a fail bit is detected for each to-be-verified data. When any one of a predetermined number of to-be-verified data does not include a fail bit, verification is determined to be a pass. When to-be-verified data including a fail bit is detected, whether the to-be-verified data is a pseudo-pass is determined depending on the count of fail-bit-containing bytes. The detailed operation will now be described.

As shown in FIG. 12, steps S51, S1 to S5, S52, and S7 to S10 are executed. In particular, sector-size to-be-verified data is transferred to the ECC processor 3 by selecting multiple addresses, and ECC-processed. After the waiting time, the level of ECC busy is determined. When the ECC busy signal is low in step S10, the to-be-verified data under processing is determined to be a true pass (step S21).

The verify controller 21 then determines whether a predetermined number of sector-size to-be-verified data pieces (8 sectors, for example) has been determined to be a true pass (step S62). If to-be-verified data remains to be unchecked for a true pass, the verify controller determined whether the next to-be-verified data is a true pass (steps S1 to S5, S62, S7 to S10, S61). After processing the predetermined number of sector-size to-be-verified data, when the true pass check register 26 is at “0”, the verification is then determined to be a true pass (step S64), and the verification is terminated.

When the ECC busy signal is high in step S10, whether the sector-size to-be-verified data under processing is a pseudo-pass is then determined. In particular, first, the verify controller 21 waits until the ECC busy signal goes low, and sets the true pass check register 26 to “1” (steps S72). The count of errors indicated by a SERR is then compared with a threshold (step S35). The threshold used in step S35 is selected based on the number of bytes including the number of fail bits allowed in sector-size to-be-verified data.

When the SERR exceeds the threshold in step S35, the verification is determined to be a fail (step S24), and the verification is terminated. If the SERR is smaller than the threshold, the sector under processing is determined to be a pseudo-pass (step S73), and steps S62 and S63 are executed. When reaching step S62 through step S73, the truth pass check register 26 is usually at “1”. Thus, the verification is determined to be a pseudo-pass (step S36), and the verification is terminated.

In the sixth embodiment, the column address may be incremented by two or more as in the fifth embodiment. In this way, sector-size to-be-verified data having a desired configuration can be generated.

As described above, in the sixth embodiment, the ECC processor determines a pass/fail of verification as in the first embodiment. Therefore, the sixth embodiment provides the same advantages as those of the first embodiment.

Further, in the sixth embodiment, fail-bit detection and pseudo-pass determination based on the count of fail-bit-containing bytes is executed in a unit, which is equal to the processing unit of the ECC processor 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory comprising an array of memory cells;
a buffer comprising latches to hold data from the memory cells, the latches constituting latch groups, the latches of each latch group being connected to corresponding one of common lines through a transfer circuit;
an error corrector that is connected to the common lines and detects an error bit in received data;
a data transfer controller that causes the buffer to read out data from memory cells to be verified in verify operation, repeats reading out of all data held in the latches in one latch group to corresponding common line as to-be-verified data segment for different latch groups, and transfers the to-be-verified data segments to the error corrector; and
a verify controller that causes the error corrector to determine whether an error bit is included in to-be-verified data comprising the to-be-verified data segments.

2. The device of claim 1, wherein:
in each of the latch groups, latches included in the latch group is commonly connected to one of selection lines,
the latches include second latch groups each comprising latches connected to the same common line, and
the data transfer controller selects all the selection lines in verify operation, and reads data held in the latches in each second latch group to one corresponding common line.

3. The device of claim 1, wherein:
the memory reads out data in units of pages,
the size of the to-be-verified data is equal to the size of the page, and
the data transfer controller transfers different to-be-verified data segments to the error corrector until the to-be-verified data is the same size as the page.

4. The device of claim 1, further comprising a busy determiner to monitor a busy signal from the error corrector, wherein
the verify controller determines verify to be a pass based on completion of a busy state after starting of output of the busy signal and to be a fail based on an asserted busy signal after starting of output of the busy signal.

5. The device of claim 1, wherein:
the error corrector outputs a signal indicating an address for an error bit in the to-be-verified data based on error detection,
the verify controller specifies a subset of the latches that includes an latch holding to-be-verified data segments that includes an error bit based on both the error detection and the received signal,
the data transfer controller selects the selection lines one by one to read out data held in the selected latch in the subset of the latches to one corresponding common line,
the error corrector sequentially receives data through the common lines, and detects an error bit in second to-be-verified data comprising a set of the received data, and
the verify controller compares the count of error bits in the second to-be-verified data with a threshold.

6. The device of claim 5, wherein:
in each of the latch groups, latches included in the latch group is commonly connected to one of selection lines,
the latches include second latch groups each comprising latches connected to the same common line, and
the data transfer controller selects all the selection lines in verify operation, and reads data held in the latches in each second latch group to one corresponding common line.

7. The device of claim 5, wherein:
the memory reads out data in units of pages,
the size of the to-be-verified data is equal to the size of the page, and
the data transfer controller transfers different to-be-verified data segments to the error corrector until the to-be-verified data is the same size as the page.

8. The device of claim 5, wherein:
the error corrector detects an error bit in units of sectors each comprising a predetermined number of bits,
the size of the to-be-verified data is equal to the size of the sector,
the data transfer controller transfers different to-be-verified data segments to the error corrector until the to-be-verified data is the same size as the sector, and
the verify controller:
causes the error corrector to determine whether the to-be-verified data includes an error whenever the to-be-verified data is received by the error corrector, and
when to-be-verified data that includes an error bit is specified, compares the count of error bits in the second to-be-verified data with a threshold to determine verify to be pass for the specified to-be-verified data based on the count of error bits equal to or smaller than the threshold and to be a fail based on the count of error bits exceeding the threshold.

9. The device of claim 5, further comprising a busy determiner to monitor a busy signal from the error corrector, wherein
the verify controller determines verify to be a pass based on completion of a busy state after starting of output of the busy signal, and starts the specification of the subset of the latches based on an asserted busy signal after starting of output of the busy signal.

10. The device of claim 5, wherein:
when the to-be-verified data includes an error bit, the verify controller instructs the memory to rewrite data to memory cells to be verified before specifying the subset of the latches, and repeats the rewriting and the detection of an error bit until the rewriting is repeated by a limit number, and
when an error bit is detected after the limit number is reached, the verify controller executes the specification of the subset of the latches, the transferring of the data held in each latch of the subset of the latches, the detection of an error bit in the second to-be-verified data, and the comparison of the count of error bits with a threshold.

11. The device of claim 10, wherein:
in each of the latch groups, latches included in the latch group is commonly connected to one of selection lines,
the latches include second latch groups each comprising latches connected to the same common line, and
the data transfer controller selects all the selection lines in verify operation, and reads data held in the latches in each second latch group to one corresponding common line.

12. The device of claim 10, wherein:
the memory reads out data in units of pages,
the size of the to-be-verified data is equal to the size of the page, and
the data transfer controller transfers different to-be-verified data segments to the error corrector until the to-be-verified data is the same size as the page.

13. The device of claim 10, further comprising a busy determiner to monitor a busy signal from the error corrector, wherein
the verify controller determines verify to be a pass based on completion of a busy state after starting of output of the busy signal, and starts the specification of the subset of the latches based on an asserted busy signal after starting of output of the busy signal.

14. The device of claim 1, wherein the verify controller receives a signal from the error corrector, compares the count of error bits in the to-be-verified data with a threshold to determine verify to be a pass based on the count of error bits equal to or smaller than the threshold and to be a fail based on the count of error bits exceeding the threshold.

15. The device of claim 14, wherein:
in each of the latch groups, latches included in the latch group is commonly connected to one of selection lines,
the latches include second latch groups each comprising latches connected to the same common line, and
the data transfer controller selects all the selection lines in verify operation, and reads data held in the latches in each second latch group to one corresponding common line.

16. The device of claim 14, wherein:
the memory reads out data in units of pages,
the size of the to-be-verified data is equal to the size of the page, and
the data transfer controller transfers different to-be-verified data segments to the error corrector until the to-be-verified data is the same size as the page.

17. The device of claim 14, further comprising a busy determiner to monitor a busy signal from the error corrector, wherein
the verify controller determines verify to be a pass based on completion of a busy state after starting of output of the busy signal, and starts the comparison of the count of error bits with the threshold based on an asserted busy signal after starting of output of the busy signal.

18. The device of claim 1, wherein:
the error corrector detects an error bit in units of sectors each comprising a predetermined number of bits,
the size of the to-be-verified data is equal to the size of the sector, and
the verify controller:
causes the error corrector to determine whether the to-be-verified data includes an error whenever the to-be-verified data is received by the error corrector, and
when to-be-verified data that includes an error bit is detected, receives a signal from the error corrector, and compares the count of error bits in the to-be-verified data with a threshold to determine verify to be pass based on the count of error bits equal to or smaller than the threshold and to be a fail based on the count of error bits exceeding the threshold.

19. The device of claim 18, wherein:
in each of the latch groups, latches included in the latch group is commonly connected to one of selection lines,
the latches include second latch groups each comprising latches connected to the same common line, and
the data transfer controller selects all the selection lines in verify operation, and reads data held in the latches in each second latch group to one corresponding common line.

20. The device of claim 18, wherein:
the data transfer controller transfers different to-be-verified data segments to the error corrector until the to-be-verified data is the same size as the sector,
the device further comprises a busy determiner to monitor a busy signal from the error corrector, and
the verify controller determines verify to be a pass based on completion of a busy state after a lapse of predetermined time from start of output of the busy signal, and starts the comparison of the count of error bits with the threshold based on an asserted busy signal after a lapse of the predetermined time.
